(19) United States
(12) Patent Application Publication
(10) Pub. No.: US 2007/0285896 A1
(43) Pub. Date: Dec. 13, 2007

(54) Packaged electronic component

(75) Inventors: Chih-Tse Chen, Taoyuan Hsien (TW); Ching-Man Kao, Taoyuan Hsien (TW); Han-Cheng Hsu, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/790,434

(22) Filed: Apr. 25, 2007

(30) Foreign Application Priority Data
May 11, 2006 (TW) 095116696

(51) Int. Cl. H05K 7/20

(52) U.S. Cl. 361/714

(57) ABSTRACT

A packaged electronic component includes a body and a thermally conductive clip. The body is made of a molding material and accommodates at least one magnetic element therein. The thermally conductive clip securely mounts on the circumference of body, and covers a top surface and a side surface of the body. The packaged electronic component is a surface mounted device (SMD).

### DETAILED DESCRIPTION OF THE INVENTION

### Cross Reference to Related Applications

This Non-provisional application claims priority under 35 U.S.C. §119(a) on Patent Application No(s). 095116696 filed in Taiwan, Republic of China on May 11, 2006, the entire contents of which are hereby incorporated by reference.

### BACKGROUND OF THE INVENTION

1. Field of Invention

The invention relates to a packaged electronic component and in particular to a packaged electronic component with a thermally conductive clip.

2. Related Art

For the sake of environmental protection, the EU has set requirements for the manufacturing processes of electronic devices. In particular, leadless processing forbids the use of lead in the manufacturing. This is because lead is harmful to both the natural environment and the human body. Therefore, leadless processing has become a rudimentary consideration in producing electronic components all over the world. Under this processing method, the soldering technique of electronic components has encountered a dramatic change. The conventional soldering material, a tin/lead alloy, can no longer be used. After some study, people have finally created leadless soldering material, such as a tin/silver/copper alloy.

FIG. 1 shows a conventional packaged electronic component 1, which is a surface mount device (SMD). In a reflow soldering process, it is irradiated by an infrared (IR) light emitted by a light source 12. The heat produced by the IR light melts the soldering material to complete the soldering. In the prior art, a tin/lead alloy is used as the material and its melting temperature is as low as around 220° C. However, leadless materials, such as the tin/silver/copper alloy has a melting temperature as high as about 260° C.

As shown in FIG. 2A, the body 11 of the packaged electronic component 1 accommodates at least one coil 112, the surface of which is covered by a silicon material 113. When the body 11 is in an environment with a reflow soldering temperature of 260° C., the silicon material 113 on the body 11 undergoes a thermal expansion. The stress thus generated is transferred to the body to produce cracks 114 on its surface, as shown in FIG. 2B. Therefore, the reliability of the process is decreased.

Therefore, it is imperative to provide a packaged electronic component that can withstand the leadless soldering process without becoming damaged.

### SUMMARY OF THE INVENTION

In view of the foregoing, the invention is to provide a packaged electronic component that can endure the leadless process without damage to the body.

To achieve the above, the invention discloses a packaged electronic component, which includes a body and a thermally conductive clip. The body is made of a molding material and accommodates at least one magnetic element therein. The thermally conductive clip securely covers at least one part of the circumference of the body.

As mentioned above, the packaged electronic component of the invention has a thermally conductive clip securely mounting on the circumference of a body. Therefore, in the high-temperature environment of a reflow soldering process, the thermally conductive clip can prevent the body from being directly exposed to the high-temperature environment. Also, the heat on the body surface can be removed by thermal conduction. Further, there are several recesses formed on the thermally conductive clip or the body for generating thermal convection. Therefore, less heat in the reflow soldering is transferred to the silicon material inside the body. In comparison with the prior art, the invention can reduce the temperature experienced by the silicon material. The circumference of the body thus does not crack due to stress produced by thermal expansion of the silicon material.

### BRIEF DESCRIPTION OF THE DRAWINGS

The invention will become more fully understood from the detailed description given herein below illustration only, and thus is not limitative of the present invention, and wherein:

FIG. 1 is a schematic view of a conventional packaged electronic component in the reflow process;

FIG. 2A is a cross-sectional view of the conventional packaged electronic component in FIG. 1 in the reflow process;

FIG. 2B is a three-dimensional view of the packaged electronic component in FIG. 2A;

FIG. 3 is a three-dimensional view of a packaged electronic component according to a preferred embodiment of the invention;

FIG. 4 is a front view of FIG. 3; and

FIG. 5 is a front view of the packaged electronic component according to another embodiment of the invention.

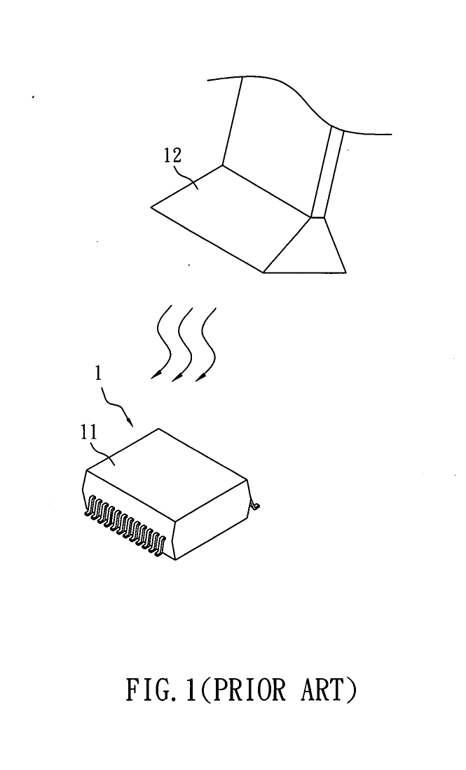

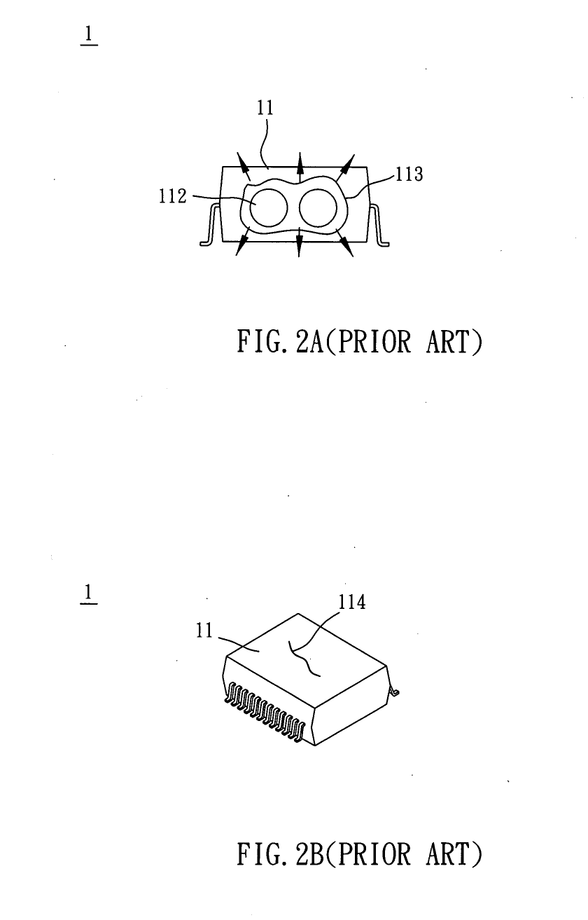

### DETAILED DESCRIPTION OF THE INVENTION

The present invention will be apparent from the following detailed description, which proceeds with reference to the accompanying drawings, wherein the same references relate to the same elements.

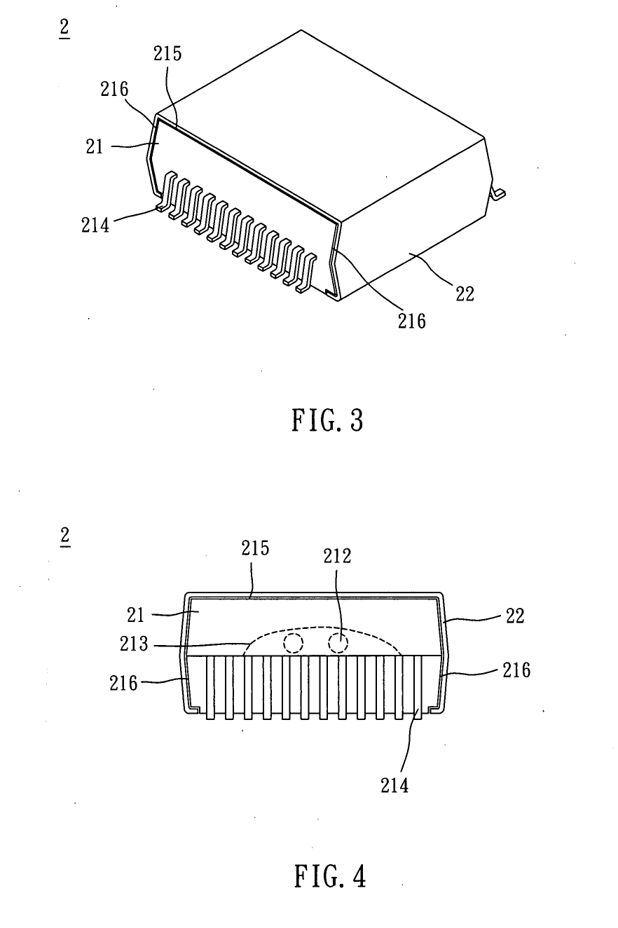

As shown in FIGS. 3 and 4, a packaged electronic component 2 according to a preferred embodiment of the invention includes a body 21 and a thermally conductive clip 22. The body 21 is made of a molding material and the body 21 accommodates at least one magnetic element 212 therein. In this embodiment, the packaged electronic component 2 is an SMD, and the magnetic element 212 is a coil as examples. The body 21 further has a silicon material 213 covering the surface of the magnetic element 212. In this embodiment, the molding material includes epoxy resins. Also, several pins 214 are disposed at two opposite sides of the body 21 for electrical connections with other equipments or devices. It is noted that the pins 214 are not in contact with the thermally conductive clip 22.

The thermally conductive clip 22 securely mounts on at least one part of the circumference of the body 21. In this embodiment, the thermally conductive clip 22 securely covers the top surface 215 and the side surface 216 of the body 21. The thermally conductive clip 22 is made of a metal material with good thermal conductivity, such as copper, in order to achieve good heat dissipation.

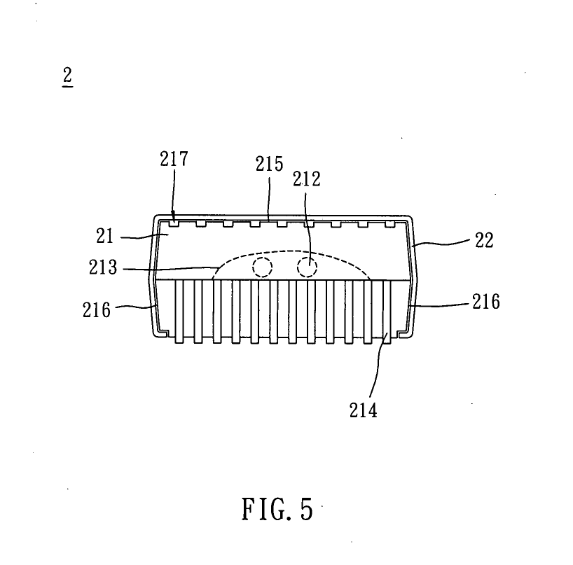

As shown in FIG. 5, the top surface 215 of the body 21 can be formed with several recesses 217 so as to further enhance the heat dissipation. Consequently, there is thermal convection between the thermally conductive clip 22 and the body 21 due to the recesses 217, in addition to thermal conduction. As the results, this makes it easier for heat to escape from the surface of the body 21. Of course, the recesses can be formed on the side surface 216 of the body 21 as well. The cross section of each recess 217 can have the shape of saw, square, or wave. Correspondingly, the surface of the thermally conductive clip 22 opposite to the top surface 215 or the side surface 216 of the body 21 can be formed with several recesses as well to further enhance heat dissipation. The cross section of each recess can have the shape of saw, square, or wave, too.

In this embodiment, the thermally conductive clip 22 securely mounting on the body 21 can dissipate heat and prevent the silicon material from a thermal expansion that causes cracks on the body 21.

In summary, the packaged electronic component of the invention has a thermally conductive clip securely mounting on the circumference of a body. Therefore, in the high-temperature environment of a reflow soldering process, the thermally conductive clip can prevent the body from being directly exposed to the high-temperature environment. Also, the heat on the body surface can be removed by thermal conduction. Further, there are several recesses formed on the thermally conductive clip or the body for generating thermal convection. Therefore, less heat in the reflow soldering is transferred to the silicon material inside the body. In comparison with the prior art, the invention can reduce the temperature experienced by the silicon material. The circumference of the body thus does not crack due to stress produced by thermal expansion of the silicon material.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A packaged electronic component, comprising:
a body accommodating at least one magnetic element therein; and
a thermally conductive clip securely mounting on the circumference of the body.

2. The packaged electronic component of claim 1, wherein the thermally conductive clip covers a top surface and a side surface of the body.

3. The packaged electronic component of claim 2, wherein the top surface of the body has a plurality of recesses.

4. The packaged electronic component of claim 3, wherein a cross section of each recess has a shape of saw, square, or wave.

5. The packaged electronic component of claim 2, wherein the side surface of the body has a plurality of recesses.

6. The packaged electronic component of claim 5, wherein a cross section of each recess has a shape of saw, square, or wave.

7. The packaged electronic component of claim 2, wherein the surface of the thermally conductive clip opposite to the body has a plurality of recesses.

8. The packaged electronic component of claim 7, wherein a cross section of each recess has a shape of saw, square, or wave.

9. The packaged electronic component of claim 1, wherein a surface of the magnetic element is covered by a silicon material.

10. The packaged electronic component of claim 1, wherein the thermally conductive clip comprises a metal material.

11. The packaged electronic component of claim 10, wherein the metal material comprises copper.

12. The packaged electronic component of claim 1, wherein the body is composed of a molding material.

13. The packaged electronic component of claim 12, wherein the molding material comprises epoxy resins.

14. The packaged electronic component of claim 1, wherein the magnetic element is a coil.

15. The packaged electronic component of claim 1 further comprising a plurality of pins disposed at two opposite sides of the body.

16. The packaged electronic component of claim 1, wherein the packaged electronic component is a surface mounted device (SMD).
